(19) United States
(12) Patent Application Publication
(10) Pub. No.: US 2025/0300446 A1
(43) Pub. Date: Sep. 25, 2025

(54) ADAPTIVE RECLOSING METHOD AND APPARATUS FOR DISTRIBUTION NETWORK, MEDIUM, AND DEVICE

(71) Applicant: Hebei University of Technology, Tianjin (CN)

(72) Inventors: Bin YANG, Tianjin (CN); Yongjian LI, Tianjin (CN); Kai HAN, Tianjin (CN)

(21) Appl. No.: 18/923,094

(22) Filed: Oct. 22, 2024

(30) Foreign Application Priority Data
Mar. 20, 2024 (CN) 202410322425.8

(51) Int. Cl. H02H 3/06; H02H 1/00

(52) U.S. Cl. CPC H02H 3/066; H02H 1/0092

(57) ABSTRACT

Provided are an adaptive reclosing method and apparatus for a distribution network, a medium, and a device, which relate to the technical field of automatic control for distribution networks. Firstly, a voltage threshold for reclosing start-up is set based on power of a load and a distributed renewable energy source that are connected in a downstream direction of a circuit breaker of a distribution network before the distribution network fails. Then, after a fault occurs in the distribution network, a positive sequence voltage amplitude and its change rate are calculated. Finally, disconnection and fault statuses of a distributed renewable energy source network are determined based on the positive sequence voltage amplitude and its change rate, and reclosing is performed based on a preset corresponding delay for different situations.

### CROSS REFERENCE TO RELATED APPLICATION

This patent application claims the benefit and priority of Chinese Patent Application No. 202410322425.8, filed with the China National Intellectual Property Administration on Mar. 20, 2024, the disclosure of which is incorporated by reference herein in its entirety as part of the present application.

### TECHNICAL FIELD

The present disclosure relates to the technical field of automatic control for distribution networks, and in particular, to an adaptive reclosing method and apparatus for a distribution network, a medium, and a device.

### BACKGROUND

At present, after a temporary fault occurs in a distribution network when a distributed renewable energy source is connected, how to reliably identify and clear the fault and quickly perform a closing operation to restore power supply is a key issue that needs to be considered. Automatic reclosing is an important means to rapidly restore the power supply of the distribution network. However, as the distributed renewable energy source is connected at a high proportion, the current national standard requires that a distributed renewable energy source connected to a grid at a voltage class of 10(6) kV to 35 kV should have a fault ride-through capability. As a result, a downstream renewable energy source may continue to operate with a fault after protective tripping. This causes reclosing failure and secondary impact to the system, seriously affecting safe operation of the distribution network. Therefore, it is urgent to study a new reclosing method suitable for a high-proportioned renewable energy source distribution network.

In the prior art, research on improving reclosing of the renewable energy source distribution network is mainly classified into three categories: increasing a delay setting, adding no-voltage verification, and adaptive reclosing. The method of increasing the delay setting is used in conjunction with renewable energy source island protection and fault ride-through to fixedly increase a reclosing delay, or called time delay of reclosure (3 s or more) to avoid influence of connecting the renewable energy source. However, the method is too time-consuming, and even the temporary fault will also cause all renewable energy sources to be disconnected from the grid, which is not conducive to rapid system recovery. The method of adding no-voltage verification identifies a disconnection status of the renewable energy source through voltage detection, but cannot distinguish a zero-voltage situation of a three-phase metallic fault, and still cannot solve impact by reclosing at the fault. The adaptive reclosing is to first determine a fault status after a circuit breaker trips, and then accelerate the reclosing if determining that a temporary fault occurs and has been cleared. Otherwise, the reclosing is shut down to prevent with the reclosing at a permanent fault.

The existing adaptive reclosing methods are mainly classified into two types: adaptive reclosing based on active injection and adaptive reclosing based on passive detection. The adaptive reclosing based on passive detection determines the fault status by detecting a free oscillation frequency, a non-fault phase induced current, a phase voltage, and other information in a line after the tripping. However, this method is designed for a transmission line with single-phase reclosing and a large oscillation time constant, and is not suitable for a situation where an oscillation component of a distribution feeder is short and three-phase tripping occurs. The adaptive reclosing based on active injection uses a grid-connected inverter or an external device to inject a high-frequency signal, a characteristic voltage, and the like into a downstream system after the tripping to determine whether the fault has been cleared. Although this method is suitable for the situation where the oscillation component of the distribution feeder is short and the three-phase tripping occurs, an additional investment for equipment costs is required, and the injected signal has a negative effect on safety of power electronic converters and sensitive loads.

### SUMMARY

Based on this, it is necessary to provide an adaptive reclosing method and apparatus for a distribution network, a medium, and a device to address the aforementioned technical problems.

This specification adopts following technical solutions.

This specification provides an adaptive reclosing method for a distribution network, including:
obtaining output power of a distributed renewable energy source and load power of a downstream connected load of a circuit breaker of a distribution network under a fault-free condition, and setting a voltage threshold for reclosing start-up based on a ratio of the output power to the load power and a rated voltage of a power system;
after a fault occurs in the distribution network and the circuit breaker trips, collecting a three-phase voltage value at a downstream outlet of the circuit breaker of the distribution network, determining a positive sequence voltage amplitude at the downstream outlet of the circuit breaker by means of fast Fourier transform (FFT) calculation and a symmetrical component method, and calculating a change rate of the positive sequence voltage amplitude;
determining whether the positive sequence voltage amplitude is less than or equal to the voltage threshold for reclosing start-up; and
if the positive sequence voltage amplitude is not less than or equal to the voltage threshold for reclosing start-up, determining that the distributed renewable energy source is disconnected from the distribution network, and performing reclosing after first delay time; or
if the positive sequence voltage amplitude is less than or equal to the voltage threshold for reclosing start-up, setting a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determining that the fault has been cleared, and performing reclosing after second delay time; and when the criterion is not met within the fault detection time limit, determining that the fault has not been cleared, and performing the reclosing after third delay time.

Optionally, the setting a voltage threshold for reclosing start-up based on a ratio of the output power to the load power and a rated voltage of a power system specifically includes:
based on the ratio of the output power to the load power and the rated voltage of the power system, calculating a predicted voltage amplitude of the distribution network from the tripping of the circuit breaker to the clearance of the fault by using a following formula:

$${U}_{After} = \sqrt{\frac{{P}_{RES}}{{P}_{Load}}} {U}_{d} = \sqrt{K} {U}_{N} ;$$

based on the predicted voltage amplitude of the distribution network after the fault is cleared, setting the voltage threshold for reclosing start-up by using a following formula:

Uₛₑₜ=0.85·U_{After}

where U_{After} represents the predicted voltage amplitude of the distribution network from the tripping of the circuit breaker to the clearance of the temporary fault, P_{RES} represents output power the output power of the distributed renewable energy source, P_{Load} represents the load power, K represents a ratio of power supply-specific active power of the renewable energy source to active power of the connected load, U_{N} represents a rated voltage amplitude of the power system before the fault occurs in the distribution network, and U_{Set} represents the voltage threshold for reclosing start-up.

Optionally, the determining a positive sequence voltage amplitude at the downstream outlet of the circuit breaker by means of FFT calculation and a symmetrical component method specifically includes:
extracting a fundamental voltage component based on the FFT calculation by using a following formula:

$$\dot{U} = {{\sum }^{M - 1}}_{n = 0} u ( n ) {e}^{- j \frac{2 π}{M}} ;$$

extracting the positive sequence voltage amplitude based on the symmetrical component method by using a following formula:

$${\dot{U}}^{+} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ] , a = {e}^{j \cdot 2 π f \cdot 120 °} ;$$

where \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network,

$${e}^{- j \frac{2 π}{M}}$$

represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an alternating current (AC) frequency of the distribution network.

Optionally, the calculating a change rate of the positive sequence voltage amplitude specifically includes:
calculating the positive sequence voltage amplitude based on a variation of the positive sequence voltage amplitude within collection time by using a following formula:

$${U}_{Der} = \frac{d ‖ {\dot{U}}^{+} ( t ) ‖}{dt} ;$$

where U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

Optionally, the setting a fault detection time limit based on the positive sequence voltage amplitude and a fault ride-through time limit of the distributed renewable energy source specifically includes:
calculating the fault detection time limit based on the positive sequence voltage amplitude and the fault ride-through time limit of the distributed renewable energy source by using a following formula:

$${t}_{Limit} = \{ \begin{matrix}0.15 , & ‖ {\dot{U}}^{+} ‖ < 0.2 p . u . \\ 1.96 \cdot ‖ {\dot{U}}^{+} ‖ + 0.23 , & 0.2 \leq ‖ {\dot{U}}^{+} ‖ < 0.9 p . u\end{matrix} ;$$

where t_{Limit} represents the fault detection time limit.

Optionally, determining whether the positive sequence voltage amplitude has the positive change rate specifically includes:
determining whether a derivative of the positive sequence voltage amplitude is greater than a preset positive threshold, and if the derivative of the positive sequence voltage amplitude is greater than the preset positive threshold, determining that the positive sequence voltage amplitude has the positive change rate, where the preset positive threshold is 5 V/ms.

This specification provides an adaptive reclosing apparatus for a distribution network, including:
a collection module configured to obtain output power of a distributed renewable energy source and load power of a downstream connected load of a circuit breaker of a distribution network under a fault-free condition, and set a voltage threshold for reclosing start-up based on a ratio of the output power to the load power and a rated voltage of a power system;
a calculation module configured to: after a fault occurs in the distribution network and the circuit breaker trips, collect a three-phase voltage value at a downstream outlet of the circuit breaker of the distribution network, determine a positive sequence voltage amplitude at the downstream outlet of the circuit breaker by means of FFT calculation and a symmetrical component method, and calculate a change rate of the positive sequence voltage amplitude; and
a determining and closing module configured to: determine whether the positive sequence voltage amplitude is less than or equal to the voltage threshold for reclosing start-up; and if the positive sequence voltage amplitude is not less than or equal to the voltage threshold for reclosing start-up, determine that the distributed renewable energy source is disconnected from the distribution network, and perform reclosing after first delay time; or if the positive sequence voltage amplitude is less than or equal to the voltage threshold for reclosing start-up, set a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determine that the fault has been cleared, and perform reclosing after second delay time; and when the criterion is not met within the fault detection time limit, determine that the fault has not been cleared, and perform the reclosing after third delay time.

This specification further provides a computer-readable storage medium. The computer-readable storage medium stores a computer program, and the computer program is executed by a processor to execute the above adaptive reclosing method for a distribution network.

This specification provides a computer device, including a memory, a processor, and a computer program stored in the memory and executable on the processor, where the processor executes the computer program to implement the above adaptive reclosing method for a distribution network.

At least one of the foregoing technical solutions adopted in this specification can achieve following beneficial effects:

Firstly, a voltage threshold for reclosing start-up is set based on power of a load and a distributed renewable energy source that are connected in a downstream direction of a circuit breaker of a distribution network before the distribution network fails. Then, after a fault occurs in the distribution network, a positive sequence voltage amplitude and its change rate are calculated. Finally, disconnection and fault statuses of a distributed renewable energy source network are determined based on the positive sequence voltage amplitude and its change rate, and reclosing is performed based on a preset corresponding delay for different situations.

The present disclosure amplifies a characteristic of a voltage rise by using the change rate of the positive sequence voltage amplitude, effectively improving detection sensitivity of fault clearance. Dual criteria, namely comparison between the positive sequence voltage amplitude and a threshold and the change rate of the positive sequence voltage amplitude, are designed to reflect the voltage rise, which can effectively avoid possible misjudgment due to a measurement error and jitter. The present disclosure is applicable to a situation where an oscillation component of a distribution feeder is short and three-phase tripping occurs, without a need for an additional device to inject a signal, thereby improving accuracy and safety of fault diagnosis in the reclosing.

### BRIEF DESCRIPTION OF THE DRAWINGS

The accompanying drawings described herein are provided for further understanding of the present disclosure, and constitute a part of the present disclosure. The exemplary embodiments of the present disclosure and illustrations thereof are intended to explain the present disclosure, but do not constitute inappropriate limitations to the present disclosure. In the accompanying drawings:

FIG. 1 is a schematic flowchart of an adaptive reclosing method for a distribution network according to this specification;

FIG. 2 is a schematic diagram of a topology for connecting a distributed renewable energy source to a distribution network according to this specification;

FIG. 3 is a schematic diagram of a waveform of a three-phase voltage at a downstream outlet of a circuit breaker according to this specification;

FIG. 4 is a schematic diagram of a positive sequence voltage amplitude at a downstream outlet of a circuit breaker according to this specification;

FIG. 5 is a schematic diagram of a calculated derivative of a positive sequence voltage amplitude according to this specification;

FIG. 6 is a schematic diagram of an adaptive reclosing apparatus for a distribution network according to this specification; and

FIG. 7 is a schematic diagram of a computer device of implementing an adaptive reclosing method for a distribution network according to this specification.

### DETAILED DESCRIPTION OF THE EMBODIMENTS

To make the objectives, technical solutions, and advantages of the present disclosure clearer, the technical solutions in the present disclosure are clearly and completely described below with reference to specific embodiments and corresponding accompanying drawings of the present disclosure. Apparently, the described embodiments are some rather than all of the embodiments of the present disclosure. All other embodiments obtained by a person of ordinary skill in the art based on the embodiments of the present disclosure without creative efforts shall fall within the protection scope of the present disclosure.

To solve a problem of secondary impact on a system due to a blind reclosing action in a distribution network under penetration of a distributed renewable energy source, the present disclosure proposes an adaptive reclosing method for a distribution network based on detection of a derivative of a positive sequence voltage amplitude. After a fault occurs and a circuit breaker trips, a fault clearance status can be reliably determined by measuring a downstream positive sequence voltage amplitude of the circuit breaker and a derivative of the downstream positive sequence voltage amplitude in real time and sensitively detecting a characteristic of a voltage rise. In addition, considering a fault ride-through time limit of the distributed renewable energy source, a reclosing delay setting solution is designed, and adaptive reclosing suitable for a high-proportioned renewable energy source distribution network is proposed. The reclosing method proposed in the present disclosure can adaptively shorten a reclosing delay based on a fault detection result and a grid disconnection/connection status of the distributed renewable energy source, greatly avoiding large-scale disconnection of the distributed renewable energy source after a temporary fault and facilitating rapid recovery of power supply.

The technical solutions provided in the embodiments of the present disclosure are described in detail below with reference to the accompanying drawings.

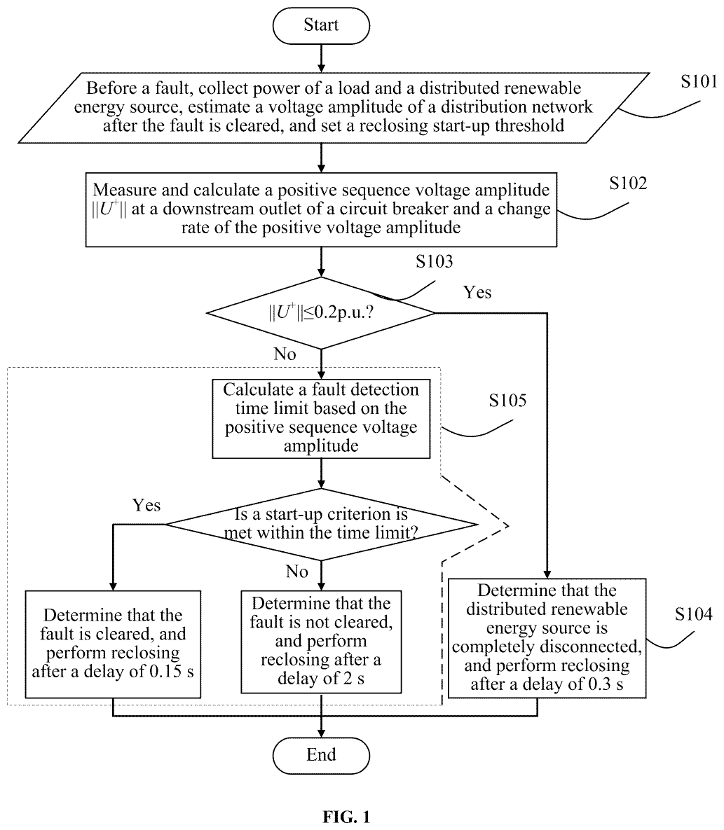

FIG. 1 is a schematic flowchart of an adaptive reclosing method for a distribution network according to this specification. The adaptive reclosing method specifically includes following steps:

S101: Obtain output power of a distributed renewable energy source and load power of a downstream connected load of a circuit breaker of a distribution network under a fault-free condition, and set a voltage threshold for reclosing start-up based on a ratio of the output power to the load power and a rated voltage of a power system.

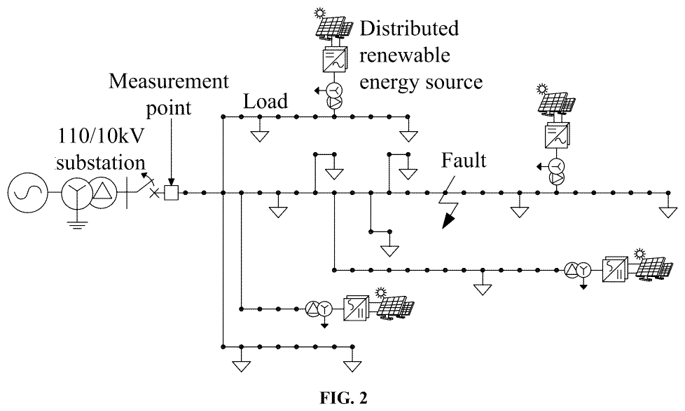

In a practical application, before a fault occurs in the distribution network, a server of a business platform can regularly collect the power of the downstream connected load of the circuit breaker of the distribution network and the power of the distributed renewable energy source. The power system is shown in FIG. 2. FIG. 2 is a schematic diagram of a topology for connecting the distributed renewable energy source to the distribution network according to this specification. Usually, the distributed renewable energy source is located in an upstream direction, and the connected load is located in a downstream direction. Before the fault occurs in the distribution network, the server can periodically obtain the load power of the downstream connected load and the output power of the distributed renewable energy source, which are detected at a measurement location.

Then, based on the ratio of the output power to the load power and the rated voltage of the power system, the server can calculate a predicted voltage amplitude of the distribution network from tripping of the circuit breaker to clearance of the fault by using a following formula:

$${U}_{After} = \sqrt{\frac{{P}_{RES}}{{P}_{Load}}} {U}_{N} = \sqrt{K} {U}_{N}$$

In the above formula, U_{After} represents the predicted voltage amplitude of the distribution network from the tripping of the circuit breaker to the clearance of the temporary fault, P_{RES} represents the output power of the distributed renewable energy source, P_{Load} represents the load power, K represents a ratio of power supply-specific active power of the renewable energy source to active power of the connected load, and U_{N} represents a rated voltage amplitude of the power system before the fault occurs in the distribution network.

After that, based on the predicted voltage amplitude of the distribution network after the fault is cleared, the server can set the voltage threshold for reclosing start-up by using a following formula:

Uₛₑₜ=0.85·U_{After}

In the above formula, U_{Set} represents the voltage threshold for reclosing start-up.

The server mentioned in this specification may be a server disposed on the business platform, or a device that can execute the solutions described in this specification, such as a desktop or a laptop. For convenience of description, the following provides description merely by taking the server as an execution entity.

S102: After the fault occurs in the distribution network and the circuit breaker trips, collect a three-phase voltage value at a downstream outlet of the circuit breaker of the distribution network, determine a positive sequence voltage amplitude at the downstream outlet of the circuit breaker by means of FFT calculation and a symmetrical component method, and calculate a change rate of the positive sequence voltage amplitude.

After the data information before the fault occurs in the distribution network is obtained, and the voltage threshold for reclosing start-up is set, when the fault occurs in the distribution network, the server can calculate the positive sequence voltage amplitude and its change rate. Thus, a fault clearance status can be determined based on the positive sequence voltage amplitude and its change rate.

Specifically, in one or more embodiments of this specification, the server can extract a fundamental voltage component based on the FFT calculation by using a following formula:

$$\dot{U} = {\sum }_{n = 0}^{M - 1} u ( n ) {e}^{- j \frac{2 π}{M}}$$

The positive sequence voltage amplitude is extracted based on the symmetrical component method by using a following formula:

$${\dot{U}}^{+} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ]$$

$$a = {e}^{j \cdot 2 π f \cdot 120 °}$$

In the above formula, \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network, which may be measured discrete voltage data,

$${e}^{- j \frac{2 π}{M}}$$

represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an AC frequency of the distribution network.

Finally, the server can calculate the positive sequence voltage amplitude based on a variation of the positive sequence voltage amplitude within collection time by using a following formula:

$${U}_{D e r} = \frac{d ‖ {\dot{U}}^{+} ( t ) ‖}{dt}$$

In the above formula, U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

To reflect a characteristic of a voltage rise that occurs when the fault is cleared, the present disclosure proposes to use a positive derivative of a voltage amplitude for mathematical representation. To adapt to different types of fault scenarios, a positive sequence component voltage is selected to calculate the derivative. The derivative of the positive sequence voltage amplitude can more intuitively characterize the characteristic of the voltage rise, and taking a derivative of ms-level time amplifies a change characteristic of a numerical value, which helps the proposed method to detect the clearance of the temporary fault more sensitively.

Usually, the collection of the three-phase voltage value at the downstream outlet of the circuit breaker of the distribution network and subsequent calculation are not performed only once, but can be performed in real time at a high frequency, so as to determine the fault clearance status of the distribution network within a period of time and perform a reclosing operation on the circuit breaker in a timely manner.

S103: Determine whether the positive sequence voltage amplitude is less than or equal to the voltage threshold for reclosing start-up. If the positive sequence voltage amplitude is not less than or equal to the voltage threshold for reclosing start-up, step S104 is performed; if the positive sequence voltage amplitude is less than or equal to the voltage threshold for reclosing start-up, step S105 is performed.

S104: Determine that the distributed renewable energy source is disconnected from the distribution network, and perform reclosing after first delay time.

S105: Set a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determine that the fault has been cleared, and perform reclosing after second delay time; and when the criterion is not met within the fault detection time limit, determine that the fault has not been cleared, and perform the reclosing after third delay time.

Referring to the process in FIG. 1, based on the comparison between the voltage threshold for reclosing start-up in the step S101 and the positive sequence voltage amplitude, the server can first determine whether a distributed renewable energy source network is disconnected. When the positive sequence voltage amplitude is less than or equal to the voltage threshold for reclosing start-up, it indicates that the new renewable energy source is disconnected from the distribution network. Therefore, the server can perform the reclosing after a preset first delay. Preferably, the first delay herein may be 0.3 s.

If it is determined at first time that the distributed renewable energy source network is not completely disconnected, the server can further determine the fault clearance status, and the fault detection time limit needs to be set first herein. Specifically, in one or more embodiments of this specification, the server can calculate the fault detection time limit based on the positive sequence voltage amplitude and the fault ride-through time limit of the distributed renewable energy source by using a following formula:

$${t}_{L i m i t} = \{ \begin{matrix}0.15 , & ‖ {\dot{U}}^{+} ‖ < 0.2 p . u . \\ 1.96 \cdot ‖ {\dot{U}}^{+} ‖ + 0.23 , & 0.2 \leq ‖ {\dot{U}}^{+} ‖ < 0.9 p . u .\end{matrix}$$

In the above formula, t_{Limit} represents the fault detection time limit, and “p.u.” represents a per-unit value. In this specification, a reference value of the per-unit value may be a voltage class of a medium voltage distribution network, namely 10 kV.

Then, within the fault detection time limit, the server can determine whether the criterion that the positive sequence voltage amplitude is greater than the voltage threshold for reclosing start-up and the positive sequence voltage amplitude has the positive change rate is met. If the criterion is met, it indicates that the fault has been cleared, and the server can perform the reclosing after a preset second delay. Preferably, the second delay herein may be 0.15 s. If the criterion is not met, next-round determining can be carried out until the fault time limit is exceeded. If the above criterion is not met within the fault detection time limit, it indicates that the fault has not been cleared, and the server can perform the reclosing after a preset third delay. Preferably, the third delay herein may be 2 s.

Certainly, in one or more embodiments of this specification, the server can determine, by using a following formula, whether the positive sequence voltage amplitude has the positive change rate:
U_{Der}>δ

In the above formula, δ represents a small value near zero. After it is determined that the fault is cleared, the reclosing is started. In theory, when the voltage rises and the derivative of the positive sequence voltage amplitude is greater than 0, it is considered that the fault is cleared. To avoid influence of a transmission error of a voltage transformer and unreliable identification of a zero value, a dead zone is added near 0. That is, whether the derivative of the positive sequence voltage amplitude is greater than a preset positive threshold is determined. If the derivative of the positive sequence voltage amplitude is greater than the preset positive threshold, the positive sequence voltage amplitude is determined to have the positive change rate. Preferably, the preset positive threshold may be 5 V/ms.

Based on the adaptive reclosing method for a distribution network in FIG. 1, a voltage threshold for reclosing start-up is set based on power of a load and a distributed renewable energy source that are connected in a downstream direction of a circuit breaker of a distribution network before the distribution network fails. Then, after a fault occurs in the distribution network, a positive sequence voltage amplitude and its change rate are calculated. Finally, disconnection and fault statuses of a distributed renewable energy source network are determined based on the positive sequence voltage amplitude and its change rate, and reclosing is performed based on a preset corresponding delay for different situations.

The present disclosure amplifies a characteristic of a voltage rise by using a derivative of the positive sequence voltage amplitude, effectively improving detection sensitivity of fault clearance. Dual criteria, namely comparison between the positive sequence voltage amplitude and a threshold and the derivative of the positive sequence voltage amplitude, are designed to reflect the voltage rise, which can effectively avoid possible misjudgment due to a measurement error and jitter, and achieve good engineering applicability. The present disclosure considers fault ride-through time of the distributed renewable energy source and integrates a reclosing delay setting solution to adaptively adjust a reclosing delay based on different fault situations, which can flexibly shorten the reclosing delay. The present disclosure is applicable to a situation where an oscillation component of a distribution feeder is short and three-phase tripping occurs, without a need for an additional device to inject a signal, thereby improving accuracy and safety of fault diagnosis in the reclosing.

When the adaptive reclosing method for a distribution network provided in this specification is applied, an execution order of each step shown in FIG. 1 may not be followed. A specific execution order of each step may be determined as needed, and is not limited in this specification.

In addition, this specification also provides an embodiment of applying the adaptive reclosing method for a distribution network provided in this specification. Firstly, a simulation system with four 100 kW distributed photovoltaic power stations connected to a 10 kV distribution feeder is built in PSCAD/EMTDC, as shown in FIG. 2. A 256 kW load is connected to a distribution network, and a circuit breaker at an outlet of a substation is equipped with three-stage current protection. All the photovoltaic power stations have a fault ride-through capability in accordance with the national standard. A voltage measurement point for adaptive reclosing is located at a downstream outlet of the circuit breaker, with a voltage signal sampling frequency of 10 kHz. After tripping, voltage data within 20 ms is intercepted each time to perform FFT calculation to calculate a downstream positive sequence voltage amplitude. A reclosing time/shut-down instruction is adjusted based on the calculated positive sequence voltage amplitude and its derivative after the tripping. Different types of temporary faults (lasting for 70 ms) and permanent faults are set at the feeder F1. At the 30^{th} ms after the fault occurs, a protection action is performed to make the circuit breaker trip. There are following fault types: an interphase fault (AB), a two-phase grounding fault (ABG), and a three-phase fault (ABC).

Before a simulated fault occurs, power of a downstream connected load of the circuit breaker of the distribution network and power of a distributed renewable energy source are collected. A power ratio is used to estimate a voltage amplitude of the distribution network after the circuit breaker trips and the fault is cleared. An estimated voltage amplitude is as follows:

$${U}_{After} = \sqrt{\frac{{P}_{R E S}}{{P}_{L o a d}}} {U}_{N} = \sqrt{K} {U}_{N} = 0.8 {U}_{N}$$

A voltage threshold for reclosing start-up is calculated based on the estimated voltage amplitude, namely:

$${U}_{S e t} = 0.85 \cdot {U}_{After} = 0 \text{.68} {U}_{N}$$

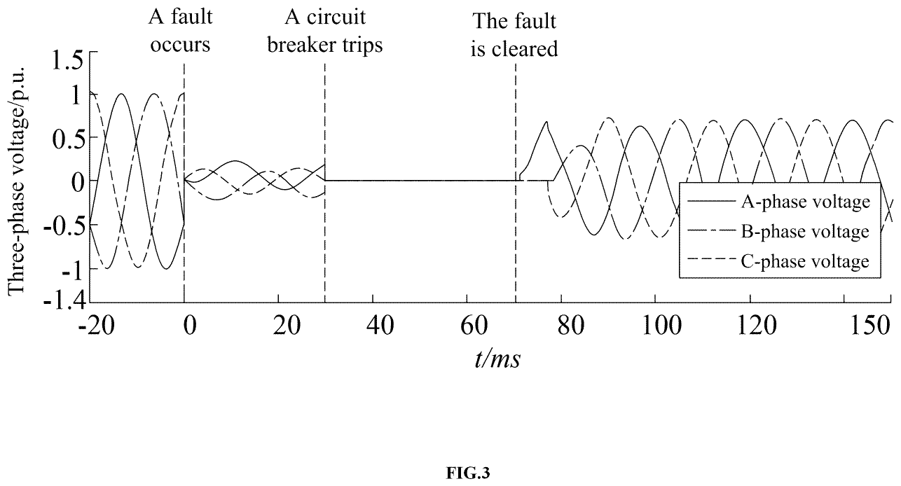

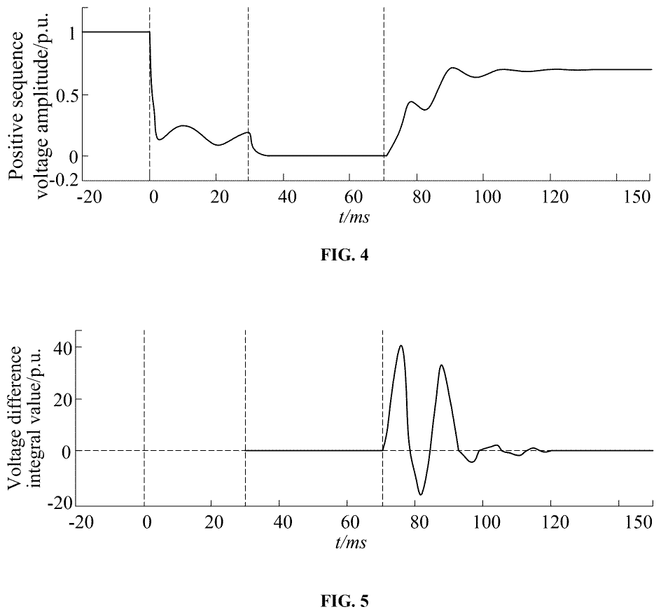

After the simulated fault occurs and the circuit breaker trips, a three-phase voltage value at the downstream outlet of the circuit breaker is collected. The positive sequence voltage amplitude is calculated by means of the FFT calculation and a symmetrical component method, and a derivative of a real-time measured positive sequence voltage amplitude is calculated. Calculation results of the three-phase voltage value, the positive sequence voltage amplitude, and the derivative of the positive sequence voltage amplitude at the downstream outlet of the circuit breaker are respectively shown in FIG. 3, FIG. 4, and FIG. 5. FIG. 3 is a schematic diagram of a waveform of the three-phase voltage at the downstream outlet of the circuit breaker in this specification. FIG. 4 is a schematic diagram of the positive sequence voltage amplitude at the downstream outlet of the circuit breaker in this specification. FIG. 5 is a schematic diagram of the calculated derivative of the positive sequence voltage amplitude in this specification.

Next, the reclosing start-up is determined. The real-time measured positive sequence voltage amplitude is compared with the above obtained voltage threshold for reclosing start-up, and the calculated derivative of the positive sequence voltage amplitude is compared with a small non-zero value. If the real-time measured positive sequence voltage amplitude is greater than the threshold and the derivative of the positive sequence voltage amplitude is greater than the small non-zero value, the reclosing start-up is allowed.

Finally, based on the real-time measured positive sequence voltage amplitude, a reclosing delay is set with reference to a fault ride-through time limit of the distributed renewable energy source. After the above start-up criterion is met, the circuit breaker is controlled to be reclosed after the delay.

Table 1 lists fault detection time for the proposed adaptive reclosing and reclosing statuses in different types of temporary fault scenarios. The detection time starts from zero time when the circuit breaker trips. After the temporary fault is cleared, a corresponding islanding voltage amplitude is 0.67 p.u.. In this case, the fault detection time limit is 1.55 s. For the permanent AB and ABG faults, a positive sequence voltage of the system is 0.265 p.u., and a corresponding fault detection time limit is 0.75 s. A detection time limit for a three-phase metallic fault is 0.2 s. If no permanent fault is detected within the corresponding time limit, reclosing is shut down.

According to Table 1, after the circuit breaker trips, the proposed fault status detection criterion can effectively distinguish between the temporary and permanent faults. For the temporary fault, compared with the current engineering method that requires a delay of 2.5 s to 3 s, the proposed method can effectively shorten the reclosing delay to be within 2 s. In this way, the reclosing time can be greatly reduced. Especially for a three-phase short-circuit fault, the proposed fault detection criterion can complete the judgement 14.6 ms after the fault is cleared, which can shorten the reclosing delay to 54.6 ms.

TABLE 1
Adaptive reclosing performance proposed
under different types of faults

| | | Detection | Reclosing |
|---|---|---|---|
| Fault type | Detection result | time/ms | instruction |
| Temporary | The clearance of the fault is | 111.25 | Reclosing after |
| AB fault | detected. | | 0.111 s |
| Permanent | The clearance of the fault is | / | Shutting down |
| AB fault | not detected within the time | | reclosing after |
| | limit. | | 0.75 s |
| Temporary | The clearance of the fault is | 111.20 | Reclosing after |
| ABG fault | detected. | | 0.111 s |
| Permanent | The clearance of the fault is | / | Shutting down |
| ABG fault | not detected within the time | | reclosing after |
| | limit. | | 0.75 s |
| Temporary | The clearance of the fault is | 54.60 | Reclosing after |
| ABC fault | detected. | | 0.055 s |
| Permanent | The clearance of the fault is | / | Shutting down |
| ABC fault | not detected within the time | | reclosing after |
| | limit. | | 0.15 s |

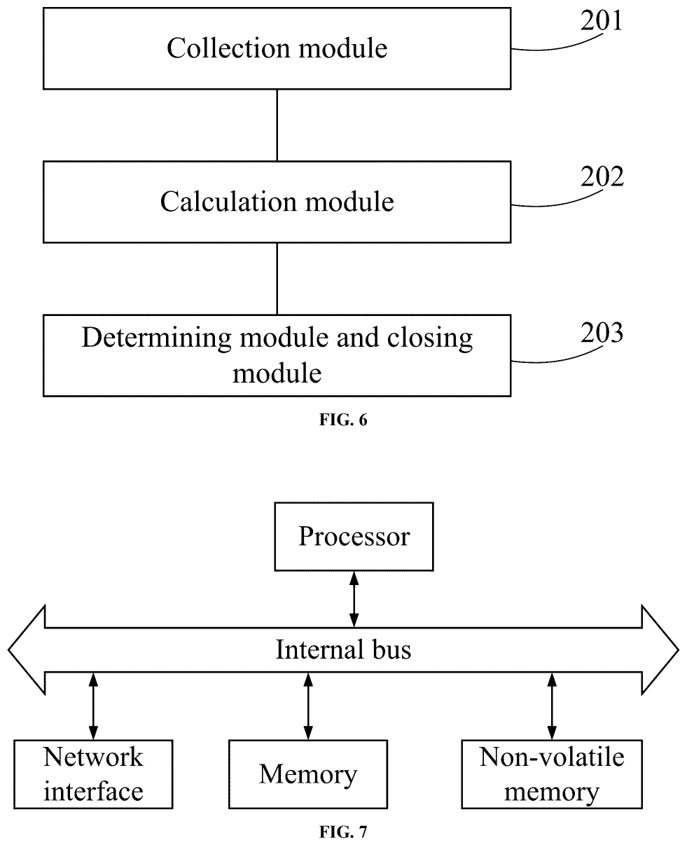

The above is the adaptive reclosing method for a distribution network provided in one or more embodiments of this specification. Based on the same idea, this specification also provides a corresponding adaptive reclosing apparatus for a distribution network, as shown in FIG. 6.

FIG. 6 is a schematic diagram of an adaptive reclosing apparatus for a distribution network according to this specification. The adaptive reclosing apparatus includes:
a collection module 201 configured to obtain output power of a distributed renewable energy source and load power of a downstream connected load of a circuit breaker of a distribution network under a fault-free condition, and set a voltage threshold for reclosing start-up based on a ratio of the output power to the load power and a rated voltage of a power system;
a calculation module 202 configured to: after a fault occurs in the distribution network and the circuit breaker trips, collect a three-phase voltage value at a downstream outlet of the circuit breaker of the distribution network, determine a positive sequence voltage amplitude at the downstream outlet of the circuit breaker by means of FFT calculation and a symmetrical component method, and calculate a change rate of the positive sequence voltage amplitude; and
a determining and closing module 203 configured to: determine whether the positive sequence voltage amplitude is less than or equal to the voltage threshold for reclosing start-up; and if the positive sequence voltage amplitude is not less than or equal to the voltage threshold for reclosing start-up, determine that the distributed renewable energy source is disconnected from the distribution network, and perform reclosing after first delay time; or if the positive sequence voltage amplitude is less than or equal to the voltage threshold for reclosing start-up, set a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determine that the fault has been cleared, and perform reclosing after second delay time; and when the criterion is not met within the fault detection time limit, determine that the fault has not been cleared, and perform the reclosing after third delay time.

Optionally, based on the ratio of the output power to the load power and the rated voltage of the power system, the collection module 201 calculates a predicted voltage amplitude of the distribution network from the tripping of the circuit breaker to the clearance of the fault by using a following formula:

$${U}_{After} = \sqrt{\frac{{P}_{R E S}}{{P}_{L o a d}}} {U}_{N} = \sqrt{K} {U}_{N} ;$$

Based on the predicted voltage amplitude of the distribution network after the fault is cleared, the voltage threshold for reclosing start-up is set by using a following formula:

Uₛₑₜ=0.85·U_{After}

In the above formula, U_{After} represents the predicted voltage amplitude of the distribution network from the tripping of the circuit breaker to the clearance of the temporary fault, P_{RES} represents the output power of the distributed renewable energy source, P_{Load} represents the load power, K represents a ratio of power supply-specific active power of the renewable energy source to active power of the connected load, U_{N} represents a rated voltage amplitude of the power system before the fault occurs in the distribution network, and U_{Set} represents the voltage threshold for reclosing start-up.

Optionally, the calculation module 202 extracts a fundamental voltage component based on the FFT calculation by using a following formula:

$$\dot{U} = {{\sum }^{M - 1}}_{n = 0} u ( n ) {e}^{- j \frac{2 π}{M}} ;$$

The positive sequence voltage amplitude is extracted based on the symmetrical component method by using a following formula:

$${\dot{U}}^{+} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ] , a = {e}^{j \cdot 2 π f \cdot 120 °} ;$$

In the above formula, \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network,

$${e}^{- j \frac{2 π}{M}}$$

represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an AC frequency of the distribution network.

Optionally, the calculation module 202 calculates the positive sequence voltage amplitude based on a variation of the positive sequence voltage amplitude within collection time by using a following formula:

$${U}_{D e r} = \frac{d ‖ {\dot{U}}^{+} ( t ) ‖}{dt} ;$$

In the above formula, U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

Optionally, the determining and closing module 203 calculates the fault detection time limit based on the positive sequence voltage amplitude and the fault ride-through time limit of the distributed renewable energy source by using a following formula:

$${t}_{L i m i t} = \{ \begin{matrix}0.15 , & ‖ {\dot{U}}^{+} ‖ < 0.2 p . u . \\ 1.96 \cdot ‖ {\dot{U}}^{+} ‖ + 0.23 , & 0.2 \leq ‖ {\dot{U}}^{+} ‖ < 0.9 p . u .\end{matrix} ;$$

In the above formula, t_{Limit} represents the fault detection time limit.

Optionally, the determining and closing module 203 determines whether a derivative of the positive sequence voltage amplitude is greater than a preset positive threshold, and if the derivative of the positive sequence voltage amplitude is greater than the preset positive threshold, determines that the positive sequence voltage amplitude has the positive change rate. The preset positive threshold is 5 V/ms.

For specific limitations on the adaptive reclosing apparatus for a distribution network, reference may be made to the above limitations on the adaptive reclosing method for a distribution network. Details are not described herein again. The modules of the adaptive reclosing apparatus for a distribution network may be implemented in whole or in part by software, hardware, or any combination thereof. The modules may be embedded in or independent of a processor of a computer device in a form of hardware, or stored in a memory of the computer device in a form of software, such that the processor can easily invoke and execute corresponding operations of the modules.

This specification further provides a computer-readable storage medium. The computer-readable storage medium stores a computer program, and the computer program can be configured to execute the adaptive reclosing method for a distribution network in FIG. 1.

This specification further provides a computer device shown in FIG. 7. As shown in FIG. 7, in terms of hardware, the computer device includes a processor, an internal bus, a network interface, a memory, and a non-volatile memory, and certainly, may also include hardware required for other businesses. The processor reads a corresponding computer program from the non-volatile memory into the memory and runs the computer program to implement the adaptive reclosing method for a distribution network in FIG. 1.

Those of ordinary skill in the art may understand that all or some of the procedures in the method of the foregoing embodiments may be implemented by a computer program instructing related hardware. The computer program may be stored in a non-volatile computer-readable storage medium. When the computer program is executed, the procedures in the embodiments of the foregoing method may be performed. Any reference used for a memory, a storage, a database, or other media used in various embodiments provided in the present disclosure may include a non-volatile memory and/or a volatile memory. The non-volatile memory may include a read-only memory (ROM), a magnetic tape, a floppy disk, a flash memory, or an optical memory. The volatile memory may include a random access memory (RAM) or an external cache memory. As an illustration rather than a limitation, the RAM may be in various forms, such as a static random access memory (SRAM) or a dynamic random access memory (DRAM).

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

What is claimed is:

1. An adaptive reclosing method for a distribution network, comprising:
obtaining output power of a distributed renewable energy source and load power of a downstream connected load of a circuit breaker of a distribution network under a fault-free condition, and setting a voltage threshold for reclosing start-up based on a ratio of the output power to the load power and a rated voltage of a power system;
after a fault occurs in the distribution network and the circuit breaker trips, collecting a three-phase voltage value at a downstream outlet of the circuit breaker of the distribution network, determining a positive sequence voltage amplitude at the downstream outlet of the circuit breaker by means of fast Fourier transform (FFT) calculation and a symmetrical component method, and calculating a change rate of the positive sequence voltage amplitude;
determining whether the positive sequence voltage amplitude is less than or equal to the voltage threshold for reclosing start-up; and
if the positive sequence voltage amplitude is not less than or equal to the voltage threshold for reclosing start-up, determining that the distributed renewable energy source is disconnected from the distribution network, and performing reclosing after first delay time; or
if the positive sequence voltage amplitude is less than or equal to the voltage threshold for reclosing start-up, setting a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determining that the fault has been cleared, and performing reclosing after second delay time; and when the criterion is not met within the fault detection time limit, determining that the fault has not been cleared, and performing the reclosing after third delay time.

2. The adaptive reclosing method for a distribution network according to claim 1, wherein the setting a voltage threshold for reclosing start-up based on a ratio of the output power to the load power and a rated voltage of a power system specifically comprises:
based on the ratio of the output power to the load power and the rated voltage of the power system, calculating a predicted voltage amplitude of the distribution network from the tripping of the circuit breaker to the clearance of the fault by using a following formula:
$${U}_{After} = \sqrt{\frac{{P}_{RES}}{{P}_{L o a d}}} {U}_{N} = \sqrt{K} {U}_{N} ;$$
based on the predicted voltage amplitude of the distribution network after the fault is cleared, setting the voltage threshold for reclosing start-up by using a following formula:
Uₛₑₜ=0.85·U_{After}
wherein U_{After} represents the predicted voltage amplitude of the distribution network from the tripping of the circuit breaker to the clearance of the temporary fault, P_{RES} represents the output power of the distributed renewable energy source, P_{Load} represents the load power, K represents a ratio of power supply-specific active power of the renewable energy source to active power of the connected load, U_{N} represents a rated voltage amplitude of the power system before the fault occurs in the distribution network, and U_{Set} represents the voltage threshold for reclosing start-up.

3. The adaptive reclosing method for a distribution network according to claim 1, wherein the determining a positive sequence voltage amplitude at the downstream outlet of the circuit breaker by means of FFT calculation and a symmetrical component method specifically comprises:
extracting a fundamental voltage component based on the FFT calculation by using a following formula:
$$\dot{U} = {\sum }_{n = 0}^{M - 1} u ( n ) {e}^{- j \frac{2 π}{M}} ;$$
extracting the positive sequence voltage amplitude based on the symmetrical component method by using a following formula:
$${\dot{U}}^{+} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ] , a = {e}^{j \cdot 2 π f \cdot 120 °} ;$$
wherein \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network,
$${e}^{- j \frac{2 π}{M}}$$
represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an alternating current (AC) frequency of the distribution network.

4. The adaptive reclosing method for a distribution network according to claim 1, wherein the calculating a change rate of the positive sequence voltage amplitude specifically comprises:
calculating the positive sequence voltage amplitude based on a variation of the positive sequence voltage amplitude within collection time by using a following formula:
$${U}_{D e r} = \frac{d ‖ {\dot{U}}^{+} ( t ) ‖}{dt} ;$$
wherein U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

5. The adaptive reclosing method for a distribution network according to claim 1, wherein the setting a fault detection time limit based on the positive sequence voltage amplitude and a fault ride-through time limit of the distributed renewable energy source specifically comprises:
calculating the fault detection time limit based on the positive sequence voltage amplitude and the fault ride-through time limit of the distributed renewable energy source by using a following formula:
$${t}_{L i m i t} = \{ \begin{matrix}0.15 , & ‖ {\dot{U}}^{+} ‖ < 0.2 p . u . \\ 1.96 \cdot ‖ \dot{U} ‖ + 0.23 , & 0.2 \leq ‖ \dot{U} ‖ < 0.9 p . u .\end{matrix} ;$$
wherein t_{Limit} represents the fault detection time limit.

6. The adaptive reclosing method for a distribution network according to claim 4, wherein determining whether the positive sequence voltage amplitude has the positive change rate specifically comprises:
determining whether a derivative of the positive sequence voltage amplitude is greater than a preset positive threshold, and if the derivative of the positive sequence voltage amplitude is greater than the preset positive threshold, determining that the positive sequence voltage amplitude has the positive change rate, wherein the preset positive threshold is 5 V/ms.

7. An adaptive reclosing apparatus for a distribution network, comprising:
a collection module configured to obtain output power of a distributed renewable energy source and load power of a downstream connected load of a circuit breaker of a distribution network under a fault-free condition, and set a voltage threshold for reclosing start-up based on a ratio of the output power to the load power and a rated voltage of a power system;
a calculation module configured to: after a fault occurs in the distribution network and the circuit breaker trips, collect a three-phase voltage value at a downstream outlet of the circuit breaker of the distribution network, determine a positive sequence voltage amplitude at the downstream outlet of the circuit breaker by means of FFT calculation and a symmetrical component method, and calculate a change rate of the positive sequence voltage amplitude; and
a determining and closing module configured to: determine whether the positive sequence voltage amplitude is less than or equal to the voltage threshold for reclosing start-up; and if the positive sequence voltage amplitude is not less than or equal to the voltage threshold for reclosing start-up, determine that the distributed renewable energy source is disconnected from the distribution network, and perform reclosing after first delay time; or if the positive sequence voltage amplitude is less than or equal to the voltage threshold for reclosing start-up, set a fault detection time limit based on the positive sequence voltage amplitude and a fault ride-through time limit of the distributed renewable energy source; and when a criterion that the positive sequence voltage amplitude is greater than the voltage threshold for reclosing start-up within the fault detection time limit and the positive sequence voltage amplitude has a positive change rate is met, determine that the fault has been cleared, and perform reclosing after second delay time; and when the criterion is not met within the fault detection time limit, determine that the fault has not been cleared, and perform the reclosing after third delay time.

8. A non-transitory computer-readable storage medium, storing a computer program, wherein the computer program is executed by a processor to execute the adaptive reclosing method according to claim 1.

9. A computer device, comprising a memory, a processor, and a computer program stored in the memory and executable by the processor, wherein the processor executes the computer program to implement the adaptive reclosing method according to claim 1.

10. The non-transitory computer-readable storage medium according to claim 8, wherein the setting a voltage threshold for reclosing start-up based on a ratio of the output power to the load power and a rated voltage of a power system specifically comprises:
based on the ratio of the output power to the load power and the rated voltage of the power system, calculating a predicted voltage amplitude of the distribution network from the tripping of the circuit breaker to the clearance of the fault by using a following formula:
$${U}_{After} = \sqrt{\frac{{P}_{RES}}{{P}_{L o a d}}} {U}_{N} = \sqrt{K} {U}_{N} ;$$
based on the predicted voltage amplitude of the distribution network after the fault is cleared, setting the voltage threshold for reclosing start-up by using a following formula:
Uₛₑₜ=0.85·U_{After}
wherein U_{After} represents the predicted voltage amplitude of the distribution network from the tripping of the circuit breaker to the clearance of the temporary fault, P_{RES} represents the output power of the distributed renewable energy source, P_{Load} represents the load power, K represents a ratio of power supply-specific active power of the renewable energy source to active power of the connected load, U_{N} represents a rated voltage amplitude of the power system before the fault occurs in the distribution network, and U_{Set} represents the voltage threshold for reclosing start-up.

11. The non-transitory computer-readable storage medium according to claim 8, wherein the determining a positive sequence voltage amplitude at the downstream outlet of the circuit breaker by means of FFT calculation and a symmetrical component method specifically comprises:
extracting a fundamental voltage component based on the FFT calculation by using a following formula:
$$\dot{U} = {\sum }_{n = 0}^{M - 1} u ( n ) {e}^{- j \frac{2 π}{M}} ;$$
extracting the positive sequence voltage amplitude based on the symmetrical component method by using a following formula:
$${\dot{U}}^{+} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ] , a = {e}^{j \cdot 2 π f \cdot 120 °} ;$$
wherein \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network,
$${e}^{- j \frac{2 π}{M}}$$
represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an alternating current (AC) frequency of the distribution network.

12. The non-transitory computer-readable storage medium according to claim 8, wherein the calculating a change rate of the positive sequence voltage amplitude specifically comprises:
calculating the positive sequence voltage amplitude based on a variation of the positive sequence voltage amplitude within collection time by using a following formula:
$${U}_{D e r} = \frac{d ‖ {\dot{U}}^{+} ( t ) ‖}{dt} ;$$
wherein U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

13. The non-transitory computer-readable storage medium according to claim 8, wherein the setting a fault detection time limit based on the positive sequence voltage amplitude and a fault ride-through time limit of the distributed renewable energy source specifically comprises:
calculating the fault detection time limit based on the positive sequence voltage amplitude and the fault ride-through time limit of the distributed renewable energy source by using a following formula:
$${t}_{L i m i t} = \{ \begin{matrix}0.15 , & ‖ {\dot{U}}^{+} ‖ < 0.2 p . u . \\ 1.96 \cdot ‖ {\dot{U}}^{+} ‖ + 0.23 , & 0.2 \leq ‖ {\dot{U}}^{+} ‖ < 0.9 p . u .\end{matrix} ;$$
wherein t_{Limit} represents the fault detection time limit.

14. The non-transitory computer-readable storage medium according to claim 12, wherein determining whether the positive sequence voltage amplitude has the positive change rate specifically comprises:
determining whether a derivative of the positive sequence voltage amplitude is greater than a preset positive threshold, and if the derivative of the positive sequence voltage amplitude is greater than the preset positive threshold, determining that the positive sequence voltage amplitude has the positive change rate, wherein the preset positive threshold is 5 V/ms.

15. The computer device according to claim 9, wherein the setting a voltage threshold for reclosing start-up based on a ratio of the output power to the load power and a rated voltage of a power system specifically comprises:
based on the ratio of the output power to the load power and the rated voltage of the power system, calculating a predicted voltage amplitude of the distribution network from the tripping of the circuit breaker to the clearance of the fault by using a following formula:
$${U}_{After} = \sqrt{\frac{{P}_{RES}}{{P}_{L o a d}}} {U}_{N} = \sqrt{K} {U}_{N} ;$$
based on the predicted voltage amplitude of the distribution network after the fault is cleared, setting the voltage threshold for reclosing start-up by using a following formula:
Uₛₑₜ=0.85·U_{After}
wherein U_{After} represents the predicted voltage amplitude of the distribution network from the tripping of the circuit breaker to the clearance of the temporary fault, P_{RES} represents the output power of the distributed renewable energy source, P_{Load} represents the load power, K represents a ratio of power supply-specific active power of the renewable energy source to active power of the connected load, U_{N} represents a rated voltage amplitude of the power system before the fault occurs in the distribution network, and U_{Set} represents the voltage threshold for reclosing start-up.

16. The computer device according to claim 9, wherein the determining a positive sequence voltage amplitude at the downstream outlet of the circuit breaker by means of FFT calculation and a symmetrical component method specifically comprises:
extracting a fundamental voltage component based on the FFT calculation by using a following formula:
$$\dot{U} = {\sum }_{n = 0}^{M - 1} u ( n ) {e}^{- j \frac{2 π}{M}} ;$$
extracting the positive sequence voltage amplitude based on the symmetrical component method by using a following formula:
$$\dot{U} = \frac{1}{3} [ \begin{matrix}1 & a & {a}^{2}\end{matrix} ] [ \begin{matrix}{\dot{U}}_{A} \\ {\dot{U}}_{B} \\ {\dot{U}}_{C}\end{matrix} ] , a = {e}^{j \cdot 2 π f \cdot 120 °} ;$$
wherein \dot{U} represents the fundamental voltage component extracted based on the FFT calculation, M represents a quantity of data points experiencing Fourier decomposition, u(n) represents the three-phase voltage value at the downstream outlet of the circuit breaker of the distribution network,
$${e}^{- j \frac{2 π}{M}}$$
represents counterclockwise rotation of a phasor by (2π/M) radians, j represents an imaginary part unit of a complex number, \dot{U}⁺ represents the positive sequence voltage amplitude at the downstream outlet of the circuit breaker, and f represents an alternating current (AC) frequency of the distribution network.

17. The computer device according to claim 9, wherein the calculating a change rate of the positive sequence voltage amplitude specifically comprises:
calculating the positive sequence voltage amplitude based on a variation of the positive sequence voltage amplitude within collection time by using a following formula:
$${U}_{D e r} = \frac{d ‖ {\dot{U}}^{+} ( t ) ‖}{dt} ;$$
wherein U_{Der} represents a calculated derivative of a positive sequence voltage amplitude of a positive sequence component, t represents the collection time, and ||\dot{U}⁺(t)|| represents a positive sequence voltage amplitude at the downstream outlet of the circuit breaker at the time t.

18. The computer device according to claim 9, wherein the setting a fault detection time limit based on the positive sequence voltage amplitude and a fault ride-through time limit of the distributed renewable energy source specifically comprises:
calculating the fault detection time limit based on the positive sequence voltage amplitude and the fault ride-through time limit of the distributed renewable energy source by using a following formula:
$${t}_{L i m i t} = \{ \begin{matrix}0.15 , & ‖ {\dot{U}}^{+} ‖ < 0.2 p . u . \\ 1.96 \cdot ‖ {\dot{U}}^{+} ‖ + 0.23 , & 0.2 \leq ‖ {\dot{U}}^{+} ‖ < 0.9 p . u .\end{matrix} ;$$
wherein t_{Limit} represents the fault detection time limit.

19. The computer device according to claim 17, wherein determining whether the positive sequence voltage amplitude has the positive change rate specifically comprises:
determining whether a derivative of the positive sequence voltage amplitude is greater than a preset positive threshold, and if the derivative of the positive sequence voltage amplitude is greater than the preset positive threshold, determining that the positive sequence voltage amplitude has the positive change rate, wherein the preset positive threshold is 5 V/ms.
